(19) United States
(12) Patent Application Publication
(10) Pub. No.: US 2022/0413072 A1
(43) Pub. Date: Dec. 29, 2022

(54) NMR METHODS FOR ANTIBODY HIGHER ORDER STRUCTURE COMPARABILITY

(71) Applicant: Regeneron Pharmaceuticals, Inc., Tarrytown, NY (US)

(72) Inventors: Igor Dikiy, New York, NY (US); William Matousek, Putnam Valley, NY (US)

(21) Appl. No.: 17/851,845

(22) Filed: Jun. 28, 2022

Related U.S. Application Data
(60) Provisional application No. 63/216,501, filed on Jun. 29, 2021.

(51) Int. Cl. G01R 33/465; G01R 33/46

(52) U.S. Cl. CPC G01R 33/465; G01R 33/4633; G01R 33/4641; G01R 33/4625

(57) ABSTRACT

The present invention generally pertains to methods of characterizing antibody higher order structure. In particular, the present invention pertains to the use of novel NMR methods to compare manufacturing process variability in antibody higher order structure.

### CROSS-REFERENCE TO RELATED APPLICATIONS

This application claims priority to and the benefit of U.S. Provisional Patent Application No. 63/216,501, filed Jun. 29, 2021 which is herein incorporated by reference.

### FIELD

This application relates to methods for comparing nuclear magnetic resonance spectroscopy and its application in manufacturing of biotechnological products.

### BACKGROUND

Protein therapeutics are complex drug substances whose safety and efficacy are dependent on a variety of critical quality attributes, including higher order structure (HOS). Characterizing HOS is essential for establishing consistency in biopharmaceutical manufacturing, detecting process-related variations from manufacturing changes and establishing comparability between biotherapeutic products.

Recently, nuclear magnetic resonance (NMR) spectroscopy methods have been developed for the characterization of HOS in therapeutic proteins, such as therapeutic antibodies. In particular, 2D heteronuclear correlated methods allow for detailed and comprehensive reporting of protein structure to the atomic level. Analysis of therapeutic proteins in the drug development process presents a particular challenge because the drug manufacturing workflow may be incompatible with isotopic labeling or enrichment, which may otherwise be used to enhance NMR signal and facilitate NMR peak assignment. Instead, advanced analytical methods may be applied to facilitate assignment, or to compare spectra using broader statistical metrics that may not require peak assignments.

Sample preparation, NMR technique, data processing, data post-processing, and data analysis are all areas currently under development for improving characterization of therapeutic proteins by NMR. To date, methods have been developed for individual lot-to-lot comparisons of therapeutic proteins. While comparing between two samples or processes is one critical component of the biotherapeutic manufacturing process, there can also be variation within a given process that can be obscured when only one representative lot is analyzed. Understanding this variation, and comparing the variation of different processes to each other, is important to selecting and optimizing a manufacturing process for biotherapeutic development.

Therefore, it will be appreciated that a need exists for NMR methods to characterize and compare process variability in manufacturing therapeutic proteins.

### SUMMARY

Methods have been developed for comparing variability of multiple manufacturing processes. The method of process-averaged easy comparability of higher order structure (ECHOS)-NMR allows for comparison of manufacturing processes without distortion by lot-to-lot variability of either process. Process-clustered principal component analysis (PCA) allows for detection and comparison of variability within each manufacturing process as well as between them. PCA clustering by process further allows for statistical analysis of said process variation relative to each principal component.

Additional improvements to NMR methods are disclosed herein. The use of IdeS as a digestive enzyme for NMR sample preparation allows for consistency in antibody fragmentation, and the production of fragments at a distinctive size range relative to other enzymes. Additionally, the use of IdeS provides an improvement in spectral resolution as compared to spectral resolution obtained without IdeS or with an intact protein. A noise elimination method is also disclosed that simplifies NMR spectra and allows for more accurate statistical analysis of analyte signal.

This disclosure provides a method for comparing manufacturing processes of proteins. In some exemplary embodiments, the method comprises (a) obtaining a plurality of protein samples from at least two manufacturing processes; (b) preparing said samples for NMR spectroscopy; (c) subjecting prepared samples to a NMR experiment; (d) obtaining NMR spectra for said samples from said NMR experiment; (e) averaging said spectra of each of said at least two manufacturing processes; and (f) comparing said averaged NMR spectra from said at least two manufacturing processes to detect differences in protein higher order structure.

In some aspects, said protein samples includes an antibody, a bispecific antibody, a multispecific antibody, antibody fragment, monoclonal antibody, antibody drug conjugate, antibody/targeted drug conjugate, conjugated monoclonal antibody, conjugated monoclonal antibody fragment, or an Fc fusion protein.

In some aspects, preparing said samples for NMR spectroscopy can include a step of contacting said samples to at least one hydrolyzing agent. In specific aspects, said hydrolyzing agent is immunoglobulin-degrading enzyme of Streptococcus pyogenes (IdeS) or a variant thereof.

In some aspects, said NMR spectra are 2D-NMR spectra. In a specific aspect, the 2D-NMR spectra are obtained using a homonuclear NMR experiment through correlation spectroscopy (COSY), total correlation spectroscopy (TOCSY) or nuclear Overhauser effect spectroscopy (NOESY). In another specific aspect, the 2D-NMR spectra are obtained using a heteronuclear NMR experiment through ¹H—¹⁵N HSQC or ¹H—¹³C HSQC. In a preferred aspect, the 2D-NMR spectra are HSQC.

In some other aspects, said NMR spectra are 3D-NMR spectra. In another aspect, said NMR spectra are 4D-NMR spectra.

In some aspects, said comparison comprises applying ECHOS-NMR on said averaged NMR spectra from said at least two manufacturing processes.

In some exemplary embodiments, the method for comparing manufacturing processes of proteins comprises: (a) obtaining a plurality of protein samples from at least two manufacturing processes; (b) preparing said samples for NMR spectroscopy; (c) subjecting said samples to a NMR experiment; and (d) subjecting resulting NMR spectra to a principal component analysis to compare manufacturing processes to detect differences in primary, secondary, and tertiary structure and higher order structure. The method for comparing manufacturing processes of proteins can also be used to compare manufacturing processes to detect differences in post translational modifications of said protein in the protein samples.

In some aspects, said protein can be an antibody, a bispecific antibody, a multispecific antibody, antibody fragment, monoclonal antibody, antibody drug conjugate, antibody/targeted drug conjugate, conjugated monoclonal antibody, conjugated monoclonal antibody fragment, or an Fc fusion protein.

In some aspects, preparing said samples for NMR spectroscopy can include a step of contacting said samples to at least one hydrolyzing agent. In specific aspects, said hydrolyzing agent is immunoglobulin-degrading enzyme of Streptococcus pyogenes (IdeS) or a variant thereof. In further aspects, preparing said samples for NMR spectroscopy can include a step of exchanging said hydrolyzed sample into a phosphate buffer.

In some aspects, said NMR spectra are 2D-NMR spectra. In a specific aspect, the 2D-NMR spectra are obtained using a homonuclear NMR experiment through correlation spectroscopy (COSY), total correlation spectroscopy (TOCSY) or nuclear Overhauser effect spectroscopy (NOESY). In another specific aspect, the 2D-NMR spectra are obtained using a heteronuclear NMR experiment through ¹H—¹⁵N HSQC or ¹H—¹³C HSQC. In a preferred aspect, the 2D-NMR spectra are HSQC.

In some aspects, said NMR spectra in said principal component analysis are clustered by manufacturing process. In specific aspects, the method further comprises subjecting said principal component analysis clusters to statistical analysis to compare manufacturing processes.

In some aspects, the method further comprises determining at least one area of said NMR spectra that contributes to at least one difference measured using principal component analysis, wherein said area is determined by plotting at least one loading as a contour plot on said NMR spectra.

In some aspects, said plurality of protein samples can be three, four, five, or more than five.

This disclosure provides additional methods for characterizing a protein. In some exemplary embodiments, the method comprises: (a) obtaining a protein sample; (b) preparing said sample for NMR spectroscopy; (c) subjecting said sample to a NMR experiment; (d) eliminating noise from empty areas of a resulting NMR spectrum; and (e) analyzing said NMR spectrum to characterize the protein.

In some aspects, step (d) comprises: (i) dividing the NMR spectrum into bins; (ii) selecting an empty area of the NMR spectrum; (iii) determining a standard deviation of signal intensity in the selected area to set a noise threshold; and (iv) adjusting the NMR spectrum signal such that all bins with signal below four times the noise threshold are set to zero. In specific aspects, said method further comprises excluding bins with an intensity of zero from analysis.

These, and other, aspects of the invention will be better appreciated and understood when considered in conjunction with the following description and accompanying drawings. The following description, while indicating various embodiments and numerous specific details thereof, is given by way of illustration and not of limitation. Many substitutions, modifications, additions, or rearrangements may be made within the scope of the invention.

### BRIEF DESCRIPTION OF THE DRAWINGS

FIG. 1A shows a raw ¹³C/¹H NMR spectrum according to an exemplary embodiment.

FIG. 1B shows a binned ¹³C/¹H NMR spectrum according to an exemplary embodiment.

FIG. 1C shows the selection of a noise area in a ¹³C/¹H NMR spectrum according to an exemplary embodiment.

FIG. 1D shows a statistical analysis of a noise area in a ¹³C/¹H NMR spectrum according to an exemplary embodiment.

FIG. 1E shows a ¹³C/¹H NMR spectrum with adjusted intensity to remove noise according to an exemplary embodiment.

FIG. 1F shows the selection of a region of interest in a ¹³C/¹H NMR spectrum according to an exemplary embodiment.

FIG. 1G shows an isolate region of interest in a ¹³C/¹H NMR spectrum according to an exemplary embodiment.

FIG. 1H shows a ¹³C/¹H NMR spectrum with normalized intensity according to an exemplary embodiment.

FIG. 1I shows a ¹³C/¹H NMR spectrum with a threshold applied to separate signal and noise areas according to an exemplary embodiment.

FIG. 1J shows a ¹³C/¹H NMR spectrum with a threshold applied to illustrate signal and noise areas according to an exemplary embodiment.

FIG. 2 shows averaged and superimposed ¹³C/¹H NMR spectra for two antibodies and two manufacturing processes, with three samples averaged per condition, according to an exemplary embodiment.

FIG. 3 shows an ECHOS-NMR analysis for two antibodies and two manufacturing processes, with three samples averaged per condition, according to an exemplary embodiment.

FIG. 4A shows a centered PCA of NMR spectra for two antibodies and two manufacturing processes, according to an exemplary embodiment.

FIG. 4B shows a non-centered PCA of NMR spectra for mAb1 and two manufacturing processes, according to an exemplary embodiment.

FIG. 4B shows a non-centered PCA of NMR spectra for mAb2 and two manufacturing processes, according to an exemplary embodiment.

FIG. 4D shows statistical analysis of a PCA of NMR spectra for two antibodies and two manufacturing processes, according to an exemplary embodiment.

### DETAILED DESCRIPTION

Protein therapeutics are complex drug substances whose safety and efficacy are dependent on a variety of critical quality attributes (CQAs). One such attribute is higher order structure (HOS), which is composed of the secondary, tertiary and quaternary structure of a drug. Characterizing HOS is important for establishing consistency in biopharmaceutical manufacturing, detecting process-related variations from manufacturing changes and establishing comparability between biotherapeutic products. However, measuring the HOS of a protein represents a substantial technical and analytical challenge. Unlike small molecule drugs that are chemically derived and for which structure can be determined absolutely, the HOS of protein therapeutics precludes absolute characterization due to their large molecular weight, protein dynamics, and product heterogeneity arising from subtle differences in the manufacturing process (Brinson et al., 2019, MAbs, 11(1):94-105).

Methods typically used for characterizing HOS of mAb drug products include Fourier transform infrared spectroscopy (FT-IR) and circular dichroism (CD). While some of these methods can be suitable to provide structural information on mAbs, they have several drawbacks for HOS characterization of protein therapeutics. Practical hardware limitations of CD require dilute protein concentrations relative to typical mAb formulations. Another issue of CD is low sensitivity, particularly when evaluating a structurally homogeneous protein like an IgG, where despite observing a change, it is not always possible to localize the structural perturbation. The degree to which results obtained at this lower concentration are predictive of behavior at higher formulation concentrations remains an open question. FT-IR can operate over a wide protein concentration range, but it is a limited single-attribute method, characterizing secondary structure only, and thus does not provide a complete measure of protein structure. Similar to CD, FT-IR is not capable of localizing any structural defect, making it a relatively low information content method. Using FT-IR, NMR spectra are usually well dispersed, providing several hundred independent readouts that can be localized to the protein sequence. The low spectroscopic and structural resolution of both techniques also makes it difficult to correlate spectral variance to structural variance. Additionally, recent studies have called into question the sensitivity of both methods to report on clinically relevant HOS variance (Arbogast et al., 2020, Curr Protoc Protein Sci, 100(1):e105).

NMR spectroscopy has been an important tool in studying protein higher order structure, but its use has traditionally depended on isotopic labeling and/or enrichment with ¹³C and ¹⁵N to achieve adequate sensitivity, which may not be compatible with biotherapeutic manufacturing processes. NMR has also generally been used for smaller molecular weight analytes, as opposed to larger molecules such as antibodies. Thus, NMR has played a limited role in structural characterization of therapeutic antibodies. However, recent advances in NMR methodology have allowed for improved sensitivity for larger analytes and for proteins at natural isotopic abundance (1.1% ¹³C, 0.3% ¹⁵N). NMR techniques useful for this application have been described, including 1D ¹H methods, 2D ¹H—¹H methods, and 2D ¹H—X heteronuclear correlated methods. Examples of the latter methods include 2D ¹³C—¹H and 2D ¹⁵N—¹H methods. Additionally, NMR data processing and post-processing techniques, or chemometric methods, have been developed for the characterization of antibodies, such as chemical shift auto-correlation, principal component analysis (PCA) and easy comparability of higher order structure (ECHOS) (Arbogast et al., supra; Amezcua and Szabo. Journal of Pharmaceutical Sciences 2013, 102 (6), 1724-1733).

The use of NMR methods for characterization of protein therapeutics is desirable because a single 2D-NMR experiment can yield a spectral map that offers a comprehensive, atomic-level fingerprint of the primary, secondary, tertiary and quaternary structure of a protein therapeutic. A correctly folded protein molecule typically affords a defined pattern of cross-peaks resulting from individual ¹⁵N—¹H amide or ¹³C—¹H methyl resonance correlations, referred to as the 2D spectral fingerprint. These signals are observed at specific frequency positions that relate to the unique chemical and structural environments of those individual atoms in the three-dimensional protein structure, assuming experimental sample conditions such as temperature, pH, and ionic strength are properly controlled. The precise matching of two 2D-NMR spectral fingerprints of a protein from two products provides a high level of assurance that the predominant structure of the proteins is highly similar between those two product samples. Such a determination of high similarity can be used to designate analytical similarity between two products in combination with other relevant CQAs (Brinson et al.).

While methods for lot-to-lot comparisons of biotherapeutic proteins using NMR have been established, applications have been limited to analyzing HOS differences between two samples or processes. While comparing between two samples or processes is one critical component of the biotherapeutic manufacturing process, there can also be variation within a given process. Being able to compare the variabilities of two or more different processes, as opposed to comparing one individual lot from each process that may or may not encapsulate the full range of products, is an important practical consideration for which methods have not yet been established. Thus, there exists an urgent need for methods for comparing manufacturing process variability in antibody higher order structure.

This disclosure sets forth novel methods for analysis of antibody manufacturing processes. A variety of advancements on conventional NMR methods are disclosed herein, including the use of IdeS as a digestive enzyme, a method for spectral noise reduction, a method for averaged ECHOS-NMR, and a method for process-grouped PCA of NMR spectra.

Unless described otherwise, all technical and scientific terms used herein have the same meaning as commonly understood by one of ordinary skill in the art to which this invention belongs. Although any methods and materials similar or equivalent to those described herein can be used in the practice or testing, particular methods and materials are now described.

The term “a” should be understood to mean “at least one” and the terms “about” and “approximately” should be understood to permit standard variation as would be understood by those of ordinary skill in the art and where ranges are provided, endpoints are included. As used herein, the terms “include,” “includes,” and “including” are meant to be non-limiting and are understood to mean “comprise,” “comprises,” and “comprising” respectively.

As used herein, the term “protein” or “pharmaceutical protein product” can include any amino acid polymer having covalently linked amide bonds. Proteins comprise one or more amino acid polymer chains, generally known in the art as “polypeptides.” “Polypeptide” refers to a polymer composed of amino acid residues, related naturally occurring structural variants, and synthetic non-naturally occurring analogs thereof linked via peptide bonds, related naturally occurring structural variants, and synthetic non-naturally occurring analogs thereof. “Synthetic peptides or polypeptides” refers to a non-naturally occurring peptide or polypeptide. Synthetic peptides or polypeptides can be synthesized, for example, using an automated polypeptide synthesizer. Various solid phase peptide synthesis methods are known to those of skill in the art. A protein may comprise one or multiple polypeptides to form a single functioning biomolecule. A protein can include antibody fragments, nanobodies, recombinant antibody chimeras, cytokines, chemokines, peptide hormones, and the like. Proteins of interest can include any of bio-therapeutic proteins, recombinant proteins used in research or therapy, trap proteins and other chimeric receptor Fc-fusion proteins, chimeric proteins, antibodies, monoclonal antibodies, polyclonal antibodies, human antibodies, and bispecific antibodies. Proteins may be produced using recombinant cell-based production systems, such as the insect bacculovirus system, yeast systems (e.g., Pichia sp.), mammalian systems (e.g., CHO cells and CHO derivatives like CHO-K1 cells). For a recent review discussing biotherapeutic proteins and their production, see Ghaderi et al., “Production platforms for biotherapeutic glycoproteins. Occurrence, impact, and challenges of non-human sialylation” (Darius Ghaderi et al., Production platforms for biotherapeutic glycoproteins. Occurrence, impact, and challenges of non-human sialylation, 28 BIOTECHNOLOGY AND GENETIC ENGINEERING REVIEWS 147-176 (2012), the entire teachings of which are herein incorporated). Proteins can be classified on the basis of compositions and solubility and can thus include simple proteins, such as globular proteins and fibrous proteins; conjugated proteins, such as nucleoproteins, glycoproteins, mucoproteins, chromoproteins, phosphoproteins, metalloproteins, and lipoproteins; and derived proteins, such as primary derived proteins and secondary derived proteins.

In some exemplary embodiments, the therapeutic protein can be present at about 1 mg/mL, about 2 mg/mL, about 3 mg/mL, about 4 mg/mL, about 5 mg/mL, about 6 mg/mL, about 7 mg/mL, about 8 mg/mL, about 9 mg/mL, about 10 mg/mL, about 15 mg/mL, about 20 mg/mL, about 25 mg/mL, about 30 mg/mL, about 35 mg/mL, about 40 mg/mL, about 45 mg/mL, about 50 mg/mL, about 55 mg/mL, about 60 mg/mL, about 65 mg/mL, about 70 mg/mL, about 75 mg/mL, about 80 mg/mL, about 85 mg/mL, about 90 mg/mL, about 95 mg/mL, about 100 mg/mL, about 110 mg/mL, about 120 mg/mL, about 130 mg/mL, about 140 mg/mL, about 150 mg/mL, about 160 mg/mL, about 170 mg/mL, about 180 mg/mL, about 190 mg/mL, about 200 mg/mL, about 225 mg/mL, about 250 mg/mL, about 275 mg/mL, about 300 mg/mL, about 325 mg/mL, about 350 mg/mL, about 375 mg/mL, or about 400 mg/mL.

In some exemplary embodiments, a therapeutic protein can be a recombinant protein, an antibody, a bispecific antibody, a multispecific antibody, antibody fragment, monoclonal antibody, fusion protein, scFv and combinations thereof.

As used herein, the term “recombinant protein” refers to a protein produced as the result of the transcription and translation of a gene carried on a recombinant expression vector that has been introduced into a suitable host cell. In certain exemplary embodiments, the recombinant protein can be an antibody, for example, a chimeric, humanized, or fully human antibody. In certain exemplary embodiments, the recombinant protein can be an antibody of an isotype selected from group consisting of: IgG (e.g., IgG1, IgG2, IgG3, IgG4), IgM, IgA1, IgA2, IgD, or IgE. In certain exemplary embodiments the antibody molecule is a full-length antibody (e.g., an IgG1 or IgG4 immunoglobulin) or alternatively the antibody can be a fragment (e.g., an Fc fragment or a Fab fragment).

The term “antibody,” as used herein includes immunoglobulin molecules comprising four polypeptide chains, two heavy (H) chains and two light (L) chains inter-connected by disulfide bonds, as well as multimers thereof (e.g., IgM). Each heavy chain comprises a heavy chain variable region (abbreviated herein as HCVR or VH) and a heavy chain constant region. The heavy chain constant region comprises three domains, CH1, CH2 and CH3. Each light chain comprises a light chain variable region (abbreviated herein as LCVR or VL) and a light chain constant region. The light chain constant region comprises one domain (CL1). The VH and VL regions can be further subdivided into regions of hypervariability, termed complementarity determining regions (CDRs), interspersed with regions that are more conserved, termed framework regions (FR). Each VH and VL is composed of three CDRs and four FRs, arranged from amino-terminus to carboxy-terminus in the following order: FR1, CDR1, FR2, CDR2, FR3, CDR3, and FR4. In different embodiments of the invention, the FRs of the anti-big-ET-1 antibody (or antigen-binding portion thereof) may be identical to the human germline sequences or may be naturally or artificially modified. An amino acid consensus sequence may be defined based on a side-by-side analysis of two or more CDRs. The term “antibody,” as used herein, also includes antigen-binding fragments of full antibody molecules. The terms “antigen-binding portion” of an antibody, “antigen-binding fragment” of an antibody, and the like, as used herein, include any naturally occurring, enzymatically obtainable, synthetic, or genetically engineered polypeptide or glycoprotein that specifically binds an antigen to form a complex. Antigen-binding fragments of an antibody may be derived, for example, from full antibody molecules using any suitable standard techniques such as proteolytic digestion or recombinant genetic engineering techniques involving the manipulation and expression of DNA encoding antibody variable and optionally constant domains. Such DNA is known and/or is readily available from, for example, commercial sources, DNA libraries (including, e.g., phage-antibody libraries), or can be synthesized. The DNA may be sequenced and manipulated chemically or by using molecular biology techniques, for example, to arrange one or more variable and/or constant domains into a suitable configuration, or to introduce codons, create cysteine residues, modify, add or delete amino acids, etc.

As used herein, an “antibody fragment” includes a portion of an intact antibody, such as, for example, the antigen-binding or variable region of an antibody. Examples of antibody fragments include, but are not limited to, a Fab fragment, a Fab′ fragment, a F(ab′)2 fragment, a scFv fragment, a Fv fragment, a dsFv diabody, a dAb fragment, a Fd′ fragment, a Fd fragment, and an isolated complementarity determining region (CDR) region, as well as triabodies, tetrabodies, linear antibodies, single-chain antibody molecules, and multi specific antibodies formed from antibody fragments. Fv fragments are the combination of the variable regions of the immunoglobulin heavy and light chains, and ScFv proteins are recombinant single chain polypeptide molecules in which immunoglobulin light and heavy chain variable regions are connected by a peptide linker. In some exemplary embodiments, an antibody fragment comprises a sufficient amino acid sequence of the parent antibody of which it is a fragment that it binds to the same antigen as does the parent antibody; in some exemplary embodiments, a fragment binds to the antigen with a comparable affinity to that of the parent antibody and/or competes with the parent antibody for binding to the antigen. An antibody fragment may be produced by any means. For example, an antibody fragment may be enzymatically or chemically produced by fragmentation of an intact antibody and/or it may be recombinantly produced from a gene encoding the partial antibody sequence. Alternatively, or additionally, an antibody fragment may be wholly or partially synthetically produced. An antibody fragment may optionally comprise a single chain antibody fragment. Alternatively, or additionally, an antibody fragment may comprise multiple chains that are linked together, for example, by disulfide linkages. An antibody fragment may optionally comprise a multi-molecular complex. A functional antibody fragment typically comprises at least about 50 amino acids and more typically comprises at least about 200 amino acids.

The term “bispecific antibody” includes an antibody capable of selectively binding two or more epitopes. Bispecific antibodies generally comprise two different heavy chains with each heavy chain specifically binding a different epitope—either on two different molecules (e.g., antigens) or on the same molecule (e.g., on the same antigen). If a bispecific antibody is capable of selectively binding two different epitopes (a first epitope and a second epitope), the affinity of the first heavy chain for the first epitope will generally be at least one to two or three or four orders of magnitude lower than the affinity of the first heavy chain for the second epitope, and vice versa. The epitopes recognized by the bispecific antibody can be on the same or a different target (e.g., on the same or a different protein). Bispecific antibodies can be made, for example, by combining heavy chains that recognize different epitopes of the same antigen. For example, nucleic acid sequences encoding heavy chain variable sequences that recognize different epitopes of the same antigen can be fused to nucleic acid sequences encoding different heavy chain constant regions and such sequences can be expressed in a cell that expresses an immunoglobulin light chain.

A typical bispecific antibody has two heavy chains each having three heavy chain CDRs, followed by a CH1 domain, a hinge, a CH2 domain, and a CH3 domain, and an immunoglobulin light chain that either does not confer antigen-binding specificity but that can associate with each heavy chain, or that can associate with each heavy chain and that can bind one or more of the epitopes bound by the heavy chain antigen-binding regions, or that can associate with each heavy chain and enable binding of one or both of the heavy chains to one or both epitopes. BsAbs can be divided into two major classes, those bearing an Fc region (IgG-like) and those lacking an Fc region, the latter normally being smaller than the IgG and IgG-like bispecific molecules comprising an Fc. The IgG-like bsAbs can have different formats such as, but not limited to, triomab, knobs into holes IgG (kih IgG), crossMab, orth-Fab IgG, Dual-variable domains Ig (DVD-Ig), two-in-one or dual action Fab (DAF), IgG-single-chain Fv (IgG-scFv), or κλ-bodies. The non-IgG-like different formats include tandem scFvs, diabody format, single-chain diabody, tandem diabodies (TandAbs), Dual-affinity retargeting molecule (DART), DART-Fc, nanobodies, or antibodies produced by the dock-and-lock (DNL) method (Gaowei Fan, Zujian Wang & Mingju Hao, Bispecific antibodies and their applications, 8 JOURNAL OF HEMATOLOGY & ONCOLOGY 130; Dafne Muller & Roland E. Kontermann, Bispecific Antibodies, HANDBOOK OF THERAPEUTIC ANTIBODIES 265-310 (2014), the entire teachings of which are herein incorporated).

As used herein “multispecific antibody” refers to an antibody with binding specificities for at least two different antigens. While such molecules normally will only bind two antigens (e.g, bispecific antibodies, bsAbs), antibodies with additional specificities such as trispecific antibody and KIH Trispecific can also be addressed by the method disclosed herein.

The term “monoclonal antibody” as used herein is not limited to antibodies produced through hybridoma technology. A monoclonal antibody can be derived from a single clone, including any eukaryotic, prokaryotic, or phage clone, by any means available or known in the art. Monoclonal antibodies useful with the present disclosure can be prepared using a wide variety of techniques known in the art including the use of hybridoma, recombinant, and phage display technologies, or a combination thereof

In some exemplary embodiments, a therapeutic protein can be produced from mammalian cells. The mammalian cells can be of human origin or non-human origin, and can include primary epithelial cells (e.g., keratinocytes, cervical epithelial cells, bronchial epithelial cells, tracheal epithelial cells, kidney epithelial cells and retinal epithelial cells), established cell lines and their strains (e.g., 293 embryonic kidney cells, BHK cells, HeLa cervical epithelial cells and PER-C6 retinal cells, MDBK (NBL-1) cells, 911 cells, CRFK cells, MDCK cells, CHO cells, BeWo cells, Chang cells, Detroit 562 cells, HeLa 229 cells, HeLa S3 cells, Hep-2 cells, KB cells, LSI80 cells, LS174T cells, NCI-H-548 cells, RPMI2650 cells, SW-13 cells, T24 cells, WI-28 VA13, 2RA cells, WISH cells, BS-C-I cells, LLC-MK2 cells, Clone M-3 cells, 1-10 cells, RAG cells, TCMK-1 cells, Y-1 cells, LLC-PKi cells, PK(15) cells, GHi cells, GH3 cells, L2 cells, LLC-RC 256 cells, MHiCi cells, XC cells, MDOK cells, VSW cells, and TH-I, B1 cells, BSC-1 cells, RAf cells, RK-cells, PK-15 cells or derivatives thereof), fibroblast cells from any tissue or organ (including but not limited to heart, liver, kidney, colon, intestines, esophagus, stomach, neural tissue (brain, spinal cord), lung, vascular tissue (artery, vein, capillary), lymphoid tissue (lymph gland, adenoid, tonsil, bone marrow, and blood), spleen, and fibroblast and fibroblast-like cell lines (e.g., CHO cells, TRG-2 cells, IMR-33 cells, Don cells, GHK-21 cells, citrullinemia cells, Dempsey cells, Detroit 551 cells, Detroit 510 cells, Detroit 525 cells, Detroit 529 cells, Detroit 532 cells, Detroit 539 cells, Detroit 548 cells, Detroit 573 cells, HEL 299 cells, IMR-90 cells, MRC-5 cells, WI-38 cells, WI-26 cells, Midi cells, CHO cells, CV-1 cells, COS-1 cells, COS-3 cells, COS-7 cells, Vero cells, DBS-FrhL-2 cells, BALB/3T3 cells, F9 cells, SV-T2 cells, M-MSV-BALB/3T3 cells, K-BALB cells, BLO-11 cells, NOR-10 cells, C3H/IOTI/2 cells, HSDMiC3 cells, KLN205 cells, McCoy cells, Mouse L cells, Strain 2071 (Mouse L) cells, L-M strain (Mouse L) cells, L-MTK′ (Mouse L) cells, NCTC clones 2472 and 2555, SCC-PSA1 cells, Swiss/3T3 cells, Indian muntjac cells, SIRC cells, Cn cells, and Jensen cells, Sp2/0, NS0, NS1 cells or derivatives thereof).

As used herein, the term “digestion” refers to hydrolysis of one or more peptide bonds of a protein. Digestion can be used in the preparation of a sample for NMR. An advantage to using digestion is to reduce the size of an analyte, which proportionally increases NMR signal for that analyte. In particular, with regards to antibodies, subdomains of antibodies may fold independently of each other, and thus cleaving the subdomains from each other provides the benefits of enhanced signal without a significant change in protein structure. There may be an additional benefit to fragmentation in facilitating the assignment of an NMR signal to a particular fragmented subdomain, without isotopic labeling or enrichment.

There are several approaches to carrying out digestion of a protein in a sample using an appropriate hydrolyzing agent, for example, enzymatic digestion or non-enzymatic digestion. As used herein, the term “digestive enzyme” refers to any of a large number of different agents that can perform digestion of a protein. Non-limiting examples of hydrolyzing agents that can carry out enzymatic digestion include protease from Aspergillus saitoi, elastase, subtilisin, protease XIII, pepsin, trypsin, Tryp-N, chymotrypsin, aspergillopepsin I, LysN protease (Lys-N), LysC endoproteinase (Lys-C), endoproteinase Asp-N (Asp-N), endoproteinase Arg-C (Arg-C), endoproteinase Glu-C (Glu-C) or outer membrane protein T (OmpT), immunoglobulin-degrading enzyme of Streptococcus pyogenes (IdeS), thermolysin, papain, pronase, V8 protease or biologically active fragments or homologs thereof or combinations thereof. For a recent review discussing the available techniques for protein digestion see Switazar et al., “Protein Digestion: An Overview of the Available Techniques and Recent Developments” (Linda Switzar, Martin Giera & Wilfried M. A. Niessen, Protein Digestion: An Overview of the Available Techniques and Recent Developments, 12 JOURNAL OF PROTEOME RESEARCH 1067-1077 (2013)). In an exemplary embodiment, the digestive enzyme is IdeS, or a variant of IdeS.

Therapeutic formulations may comprise components that are not suitable for use in NMR analysis. For example, excipients or buffers that comprise hydrogen atoms may produce an undesirable NMR signal that interfere with detection of the protein analyte. In such a case, a buffer exchange or dialysis step may be used to transfer the protein analyte to a suitable buffer. In an exemplary embodiment, the analyte is dialyzed into a buffer comprising 10 mM sodium phosphate at pH 6.0.

As used herein, the term “nuclear magnetic resonance” (“NMR”) refers to nuclear magnetic resonance spectroscopy, a technique used to observe local magnetic fields around atomic nuclei. An NMR signal is produced by excitation of the nuclei of an analyte sample with radio waves into nuclear magnetic resonance, which is then detected with radio receivers. The resulting NMR spectra provide information about the structure, dynamics, reaction state, and chemical environment of an analyte molecule. There are a variety of distinct NMR techniques that can be selected depending on the analyte and the desired data. NMR techniques relevant to protein analysis include, for example, 1D ¹H methods, 2D ¹H—¹H methods, and 2D ¹H—X heteronuclear correlated methods, including 2D ¹³C—¹H and 2D ¹⁵N—¹H methods. In an exemplary embodiment, the NMR method used to compare manufacturing processes is a 2D ¹³C—¹H method.

Within the realm of 2D heteronuclear NMR, there exists a subset of alternative methods, including heteronuclear single-quantum correlation (HSQC), heteronuclear multiple-quantum correlation spectroscopy (HMQC), and heteronuclear multiple-bond correlation spectroscopy (HMBC). Unless otherwise indicated, experiments disclosed herein employ HSQC. However, the disclosed methods may be also be applied to any type of multidimensional NMR experiment including using HMQC or HMBC.

NMR spectra can be subjected to additional analysis in order to further interpret the rich data set inherent in each spectrum. As used herein, the terms “data processing”, “data post- processing”, or “chemometric” are used to describe methods for the analysis of NMR data after acquisition. A number of software programs exist that can be used to facilitate data processing, for example, JMP 15 (SAS Institute, Inc.) or MATLAB (Mathworks). Any suitable software capable of manipulating large data sets may be selected.

NMR data can be further analyzed using, for example, easy comparability of higher order structure by NMR (ECHOS-NMR) (Amezcua et al., 2013, J Pharm Sci, 102(6):1724-1733). ECHOS-NMR involves comparing the similarity between two experimental samples by measuring the correlation coefficient derived from a linear regression analysis of binned NMR spectral intensities. This method allows for making a direct, relative comparison of overall similarities between two analytes without the need for isotopic labeling or enrichment. In an exemplary embodiment, the method of ECHOS-NMR is further applied to averaged spectra from two manufacturing processes, and thus used to compare two processes instead of two samples.

A common statistical method for analysis of large data sets is principal component analysis (PCA). PCA is commonly used for dimensionality reduction by projecting each data point onto only the first few principal components, which represent dimensions of the data set with the highest variance, to obtain lower-dimensional data while preserving as much of the data's variation as possible. Principal components may be computed by eigendecomposition of the data covariance matrix. In an exemplary embodiment, each data point on a PCA plot represents an NMR spectrum. In an exemplary embodiment, data points on a PCA plot may be clustered according to the manufacturing process of the analyte antibody. In an exemplary embodiment, these clusters can be subjected to additional statistical analysis in order to compare variance of each manufacturing process to the other.

While ECHOS-NMR or PCA are abstracted from the exact chemical structure of the NMR analyte, statistical differences or variances between NMR spectra detected using these, or other, statistical methods can be correlated with alternative analytical methods in order to determine the specific chemical source of each difference or variation.

It is understood that the present invention is not limited to any of the aforesaid protein(s), antibody(s), NMR technique(s), digestive enzyme(s), data processing method(s), or data post-processing method(s), and any protein(s), antibody(s), NMR technique(s), digestive enzyme(s), data processing method(s), or data post-processing method(s) can be selected by any suitable means.

The present invention will be more fully understood by reference to the following Examples. They should not, however, be construed as limiting the scope of the invention.

### EXAMPLES

Sample Preparation. NMR experiments were performed with mAb1 and mAb2 lot samples manufactured using two different manufacturing processes, Process 1 and Process 2. mAb1 and mAb2 lot samples were digested in situ with immobilized IdeS (Genovis FraglT columns), dialyzed into 10 mM sodium phosphate, pH 6.0, and concentrated to 40 mg/mL for NMR experiments.

NMR Data Collection. The one-dimensional ¹H and two-dimensional ¹³C/¹H NMR spectra were obtained using standard Bruker pulse sequences (zgesgp, or 1D sequence with water suppression using excitation sculpting with gradients; and hsqcetgpsp, or 2D H-1/X correlation via double inept transfer, phase sensitive using Echo/Antiecho-TPPI gradient selection) on a Bruker spectrometer operating at 800 MHz (1H frequency) using a cryogenically-cooled probe at 45° C. Two-dimensional spectra were collected with 50% non-uniform sampling.

NMR Data Processing and Post-Processing. The one-dimensional ¹H and two-dimensional ¹³C/¹H NMR spectra were processed using NMRFx Processor (One Moon Scientific, Inc) and raw spectral intensities were exported, then imported into JMP 15 (SAS Institute, Inc). For process-to-process comparisons, spectra collected on representative lots/samples from each process were averaged after NMRFx processing to generate average spectra representing each process. These average spectra can then be treated the same as directly collected data.

One-dimensional spectra were analyzed either as whole spectra or broken down into amide (6.0-11.5 ppm ¹H) and aliphatic (−1.0-3.5 ppm ¹H) regions. No noise removal or normalization was performed on one-dimensional spectra.

Two-dimensional spectra were subjected to binning, noise removal, and normalization. The two-dimensional spectrum was divided into bins of width 0.054 ppm in the ¹H dimension and height 0.406 ppm in the ¹³C dimension, since this is roughly the size of each methyl peak, and the signal within each bin averaged. To remove noise, the standard deviation of signal intensity in an empirically-determined “noise region” (−1.5 to −1.0 ppm ¹H) was calculated, then all bins with signal below two times that noise threshold were set to zero. This also served the purpose of setting all negative signal, which is not expected in this experiment, to zero. Finally, the bins within the methyl region (−1.0-2.5 ppm ¹H, 10.8-28 ppm ¹³C) were normalized to the highest intensity bin in that region to account for minor variations in concentration.

NMR Data Analysis. Vectors representing the one-dimensional ¹H and two-dimensional ¹³C/¹H NMR spectra, after post-processing, were compared either using ECHOS-NMR or PCA analyses.

For ECHOS-NMR, vectors representing two spectra were directly correlated in JMP 15. The R² value (high indicates similarity), RMSE (low indicates lack of differences), and % CV (coefficient of variation, which is RMSE scaled by the mean signal; low indicates lack of difference) were reported for each pairwise comparison. For two-dimensional datasets, points in which the intensity was zero for both datasets being compared were excluded from ECHOS-NMR analysis.

For PCA, vectors representing several spectra (e.g., several representative spectra from two processes) were analyzed using the Principal Components platform implemented in JMP 15, using the Pair-wise estimation method, with principal components created based on covariances. During the PCA, bins with no variation among the datasets were dropped from analysis.

For comparison of several groups (e.g., different manufacturing processes), the scores of the top two principal components were plotted against each other and 95% confidence density ellipses grouped by the category to be compared were plotted. The means and standard deviations of the ellipses can be used for a statistical comparison of groups (t-test) or plotted for visual inspection, leading to a finding of comparability or lack of comparability.

Principal components in which relevant differences between groups are observed can be further analyzed as to the source of the difference. Loadings (coefficients that transform the spectral bins into the principal components) for the principal component of interest can be plotted as a contour plot on the original spectrum chemical shift axes, resulting in a “virtual spectrum” showing areas strongly contributing to differences along this principal component. In the case of two clusters/processes that are separated along one principal component, this loadings plot essentially replicates a difference spectrum of the two groups, allowing differences to be pinpointed with high resolution on the analyte.

### Example 1

### Improvement of NMR Methods

Conventional NMR methods were refined for quantitative analysis of antibody higher order structure (HOS).

In preparing an antibody for NMR analysis, the antibody may be digested by a digestive enzyme in order to produce smaller fragments for higher NMR signal and higher resolution analysis. Conventional digestion of an antibody for NMR analysis may use as a digestive enzyme, for example, papain, which digests an antibody at a non-specific site and produces antibody fragments of roughly 50, 50 and 50 kDa. For the present analysis, the enzyme IdeS was used. IdeS, and related enzymes, cleave a specific, predictable antibody site below the hinge region, allowing for greater comparability between experiments compared to conventional methods. Additionally, IdeS produces antibody fragments of roughly 100, 25 and 25 kDa, providing a distinctive result in terms of NMR signal quality and intensity, which vary with analyte size. The digestion was noted to not impact the spectral dispersion of the mAb significantly.

For post-processing analysis of NMR data, a novel noise reduction method was tested and employed. A large region in, for example, two-dimensional ¹³C/¹H NMR spectra may contain no signal from the protein analyte and solely comprise noise. Inclusion of this noise in subsequent analysis may distort, for example, correlation using ECHOS-NMR or PCA.

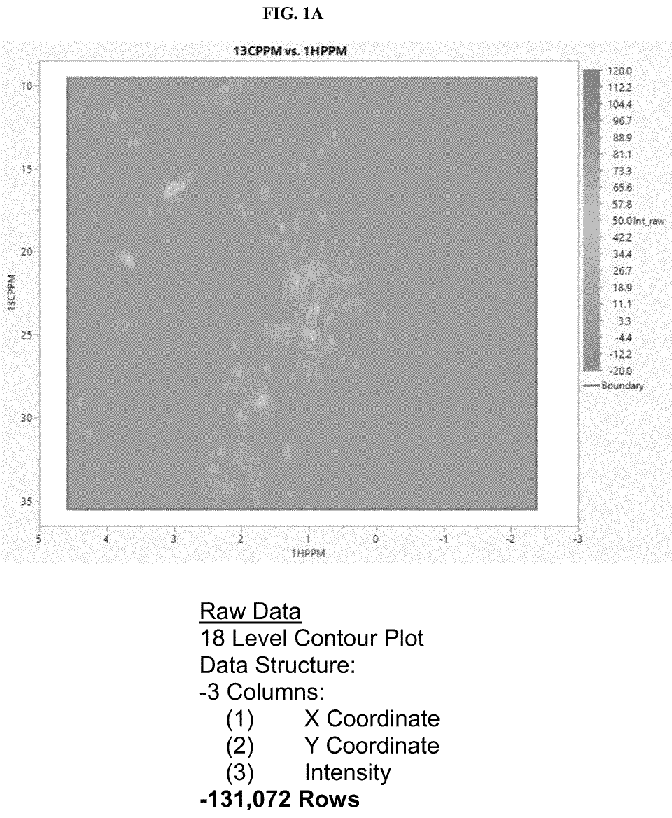

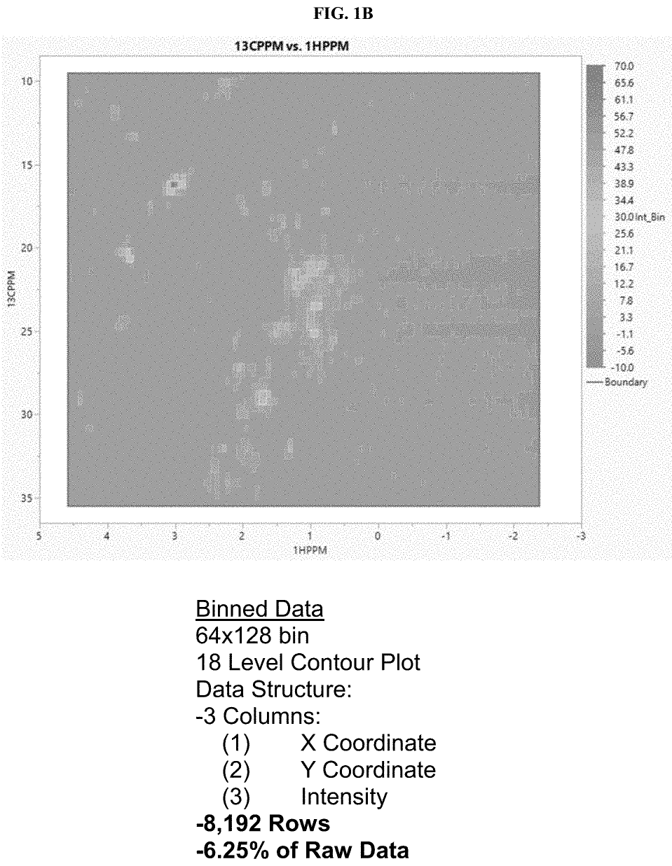

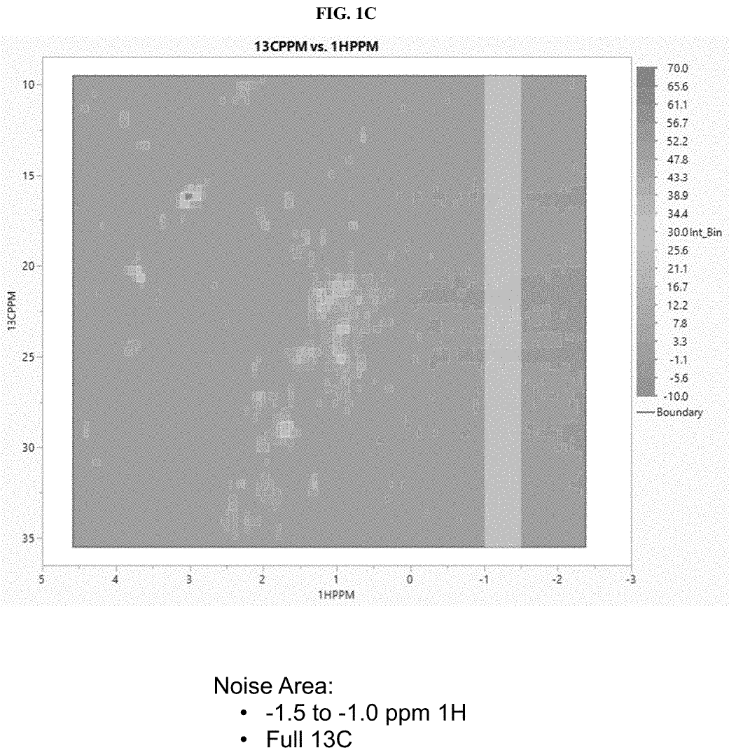

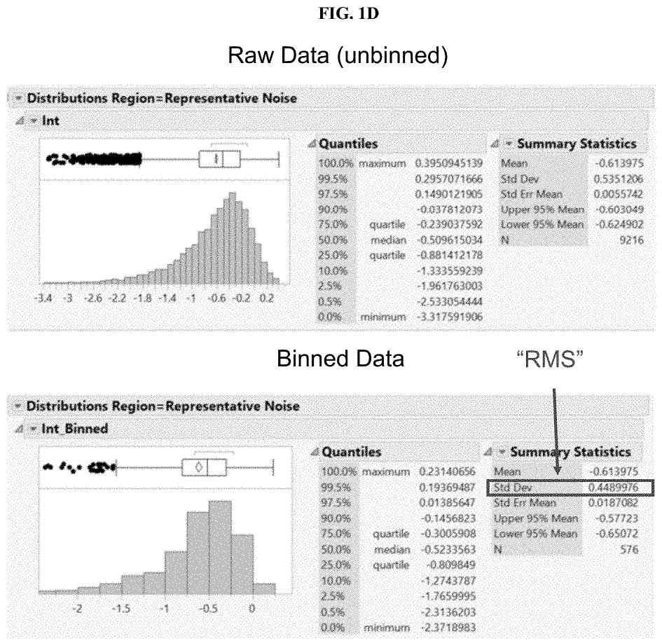

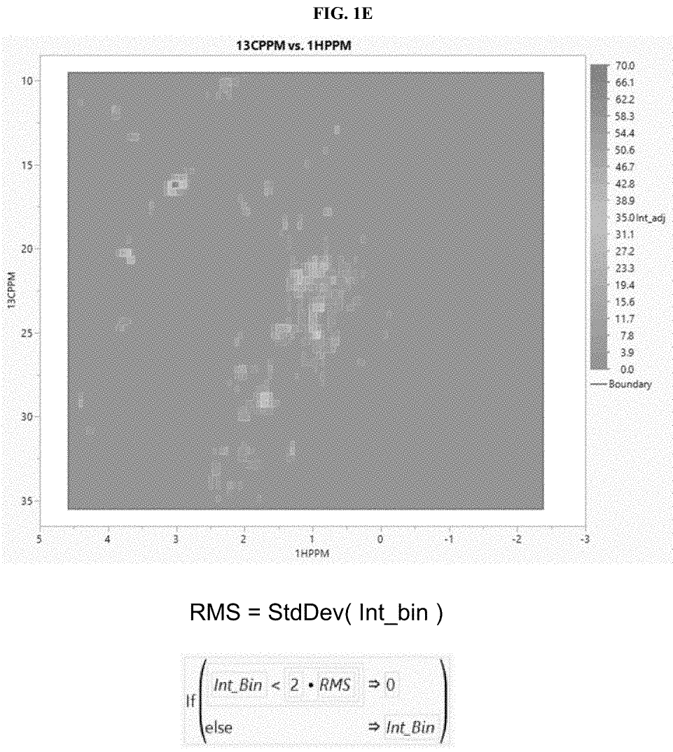

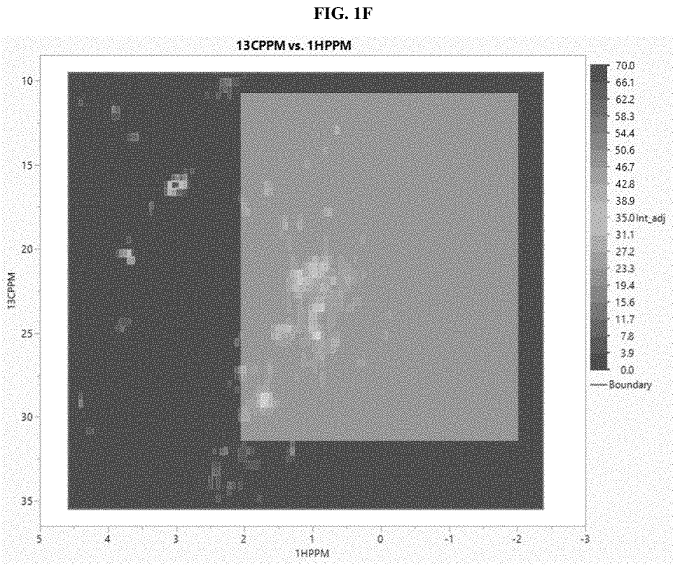

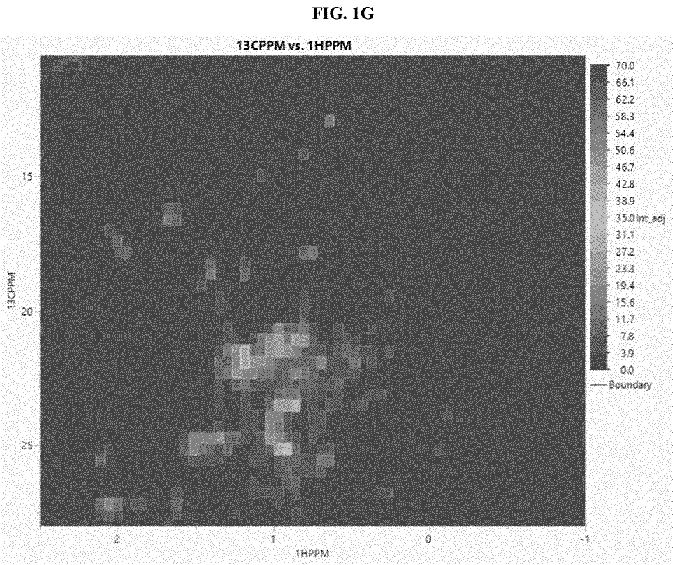

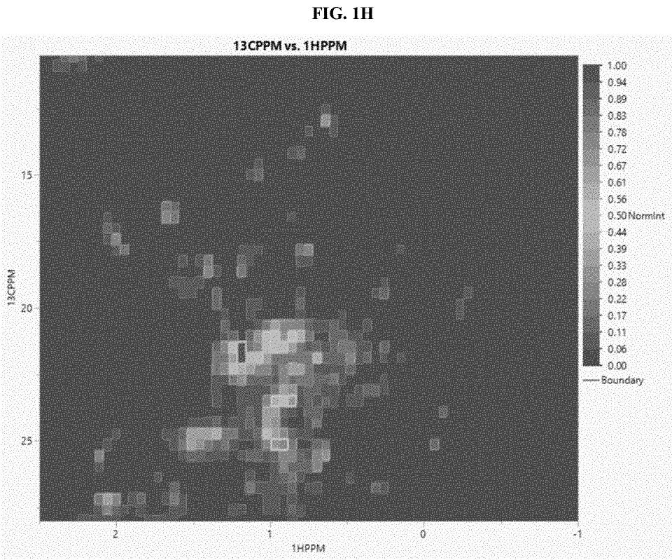

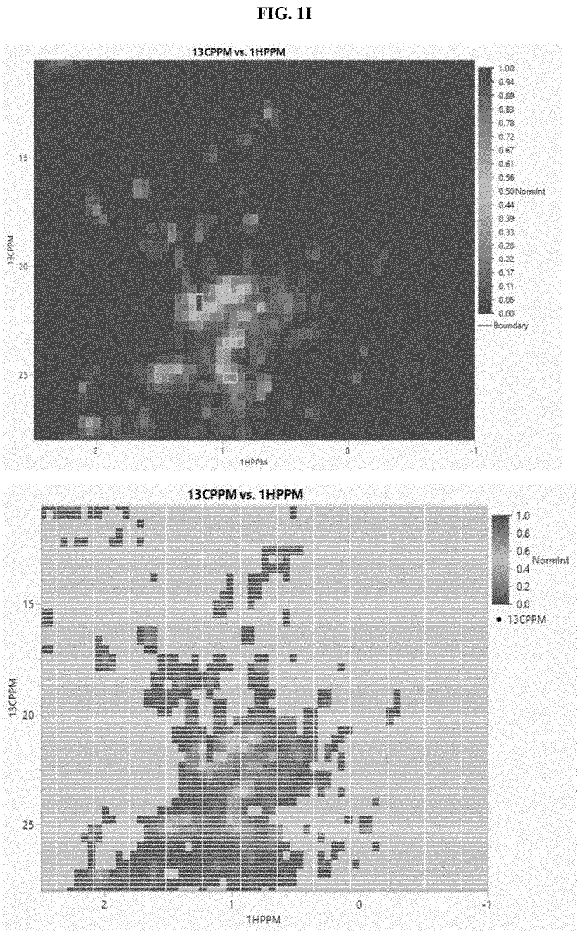

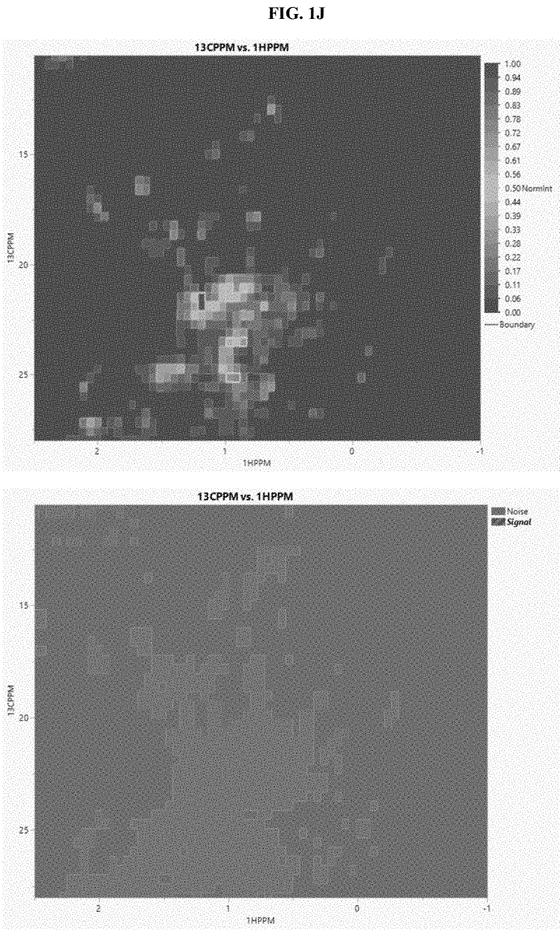

An exemplary method of NMR data analysis, including noise elimination and signal normalization, is depicted in FIG. 1. Raw data was gathered as shown in FIG. 1A, and binned as shown in FIG. 1B. An “empty” region comprising no signal from the analyte was selected as shown in FIG. 1C, and a noise threshold was set based on the standard deviation of values from this region, as shown in FIG. 1D. An adjusted intensity was then calculated and applied to exclude this noise as shown in FIG. 1E, simplifying the NMR spectra. This novel noise removal process allows for more accurate quantitative analysis of NMR data and was used for the experiments described below.

Normalization of signal intensity was conducted to control for technical variation between experiments. A region of interest was identified and isolated as shown in FIG. 1F and FIG. 1G. The intensity of the bins within the region of interest were normalized to the highest intensity bin of the region of interest, in order to facilitate quantitative comparison between spectra, as shown in FIG. 1H.

Using the adjusted and normalized intensity from the previous steps, signal regions of the spectrum could be separated from noise regions of the spectrum as shown in FIG. 1I and FIG. 1J.

### Example 2

### Assessment of Process Variability in mAb Manufacturing

Two monoclonal antibodies, mAb1 and mAb2, were each manufactured using two different processes, Process 1 and Process 2. In order to analyze process variability of both processes in terms of antibody higher order structure (HOS), novel NMR techniques were developed.

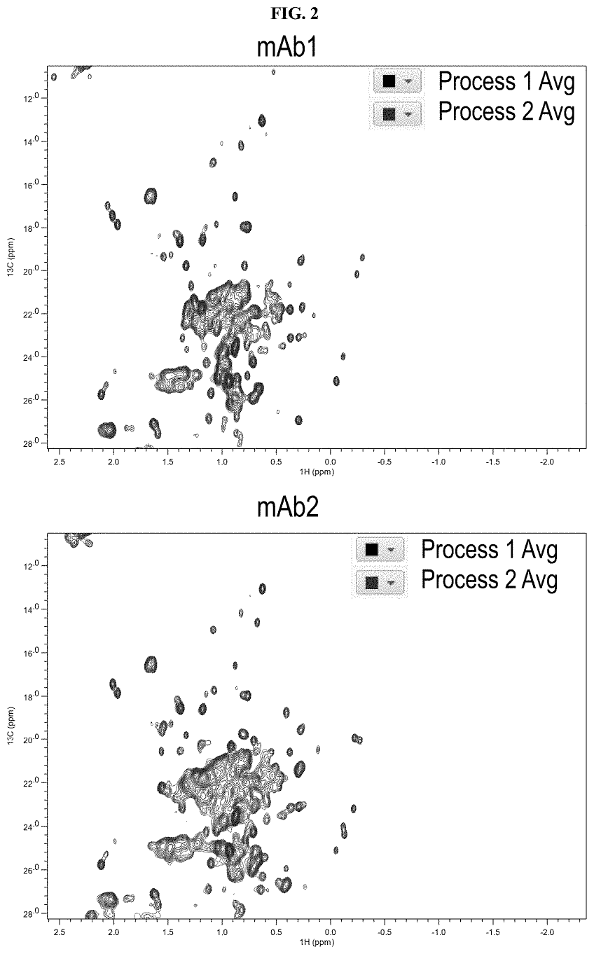

Three lots of mAb1 and mAb2 manufactured according to Process 1 and Process 2 were analyzed using NMR, as described above. The ¹³C/¹H spectra for each antibody for each process were averaged and superimposed as shown in FIG. 2. The spectra from Process 1 are shown in black, and the spectra from Process 2 are shown in red. The superimposed averaged spectra show that there is very little variation between processes. This method of spectral averaging and superimposition allows for easy visual analysis of process variability in antibody HOS. Averaging NMR spectra for each antibody for each process removes small effects of lot-to-lot variations, and allows for analysis of significant differences between sites for each process.

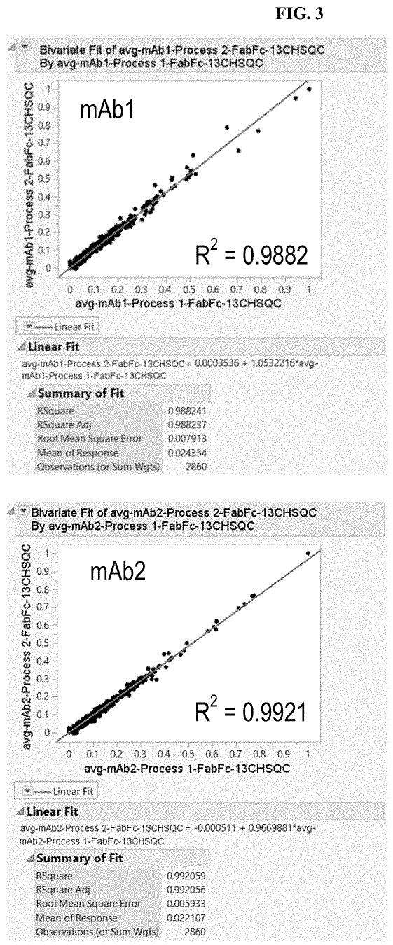

Further comparison between manufacturing processes was carried out using ECHOS-NMR. Averaged spectra for each antibody for each process were correlated as shown in FIG. 3. For both antibodies, the two manufacturing processes were highly comparable, as measured both by the coefficient of determination (R²) and root-mean-square error (RMSE). The processes for mAb2 were possibly more comparable. The use of averaged spectra for ECHOS-NMR analysis allowed for robust comparison between manufacturing processes, compensating for any lot-to-lot variability.

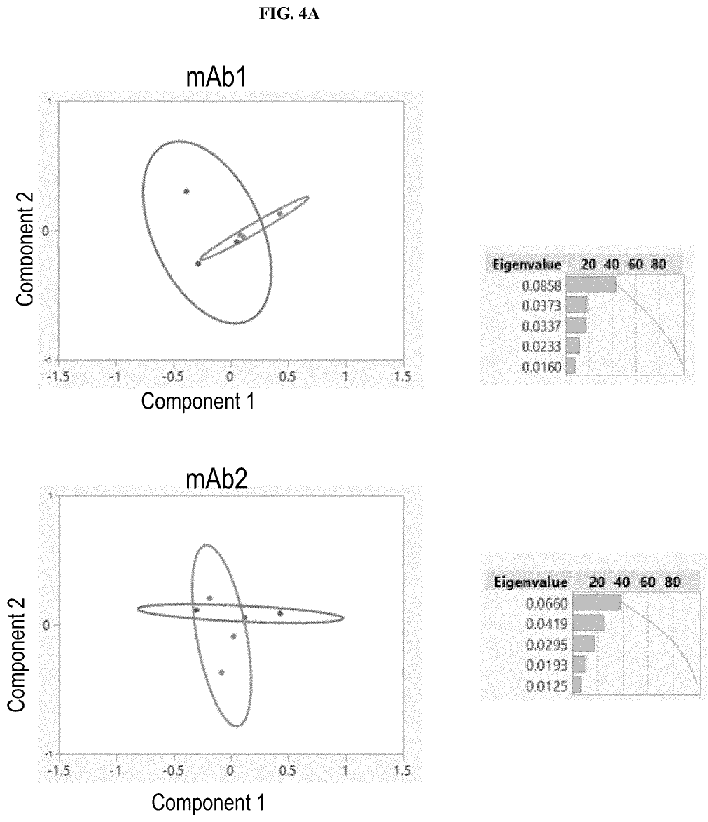

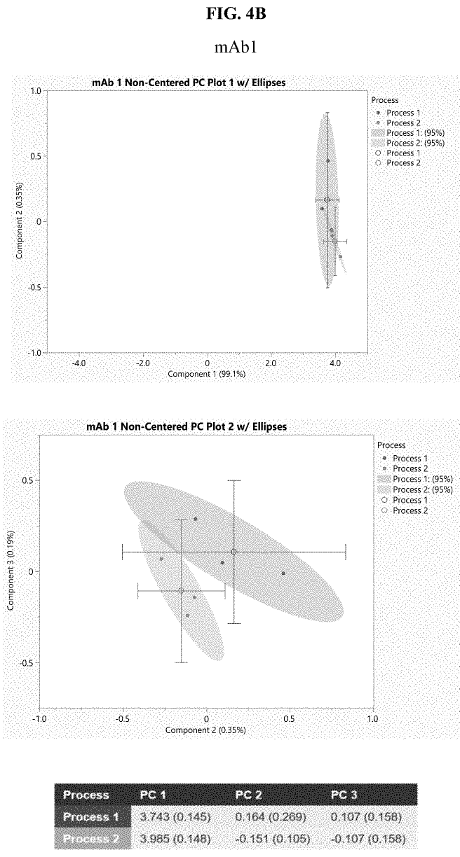

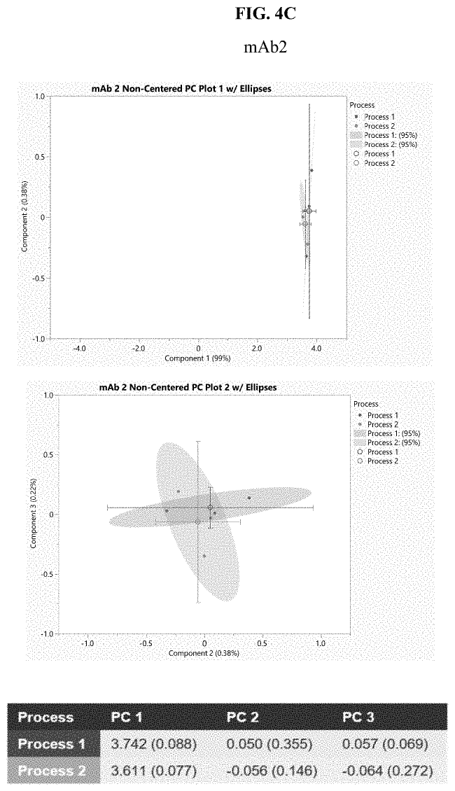

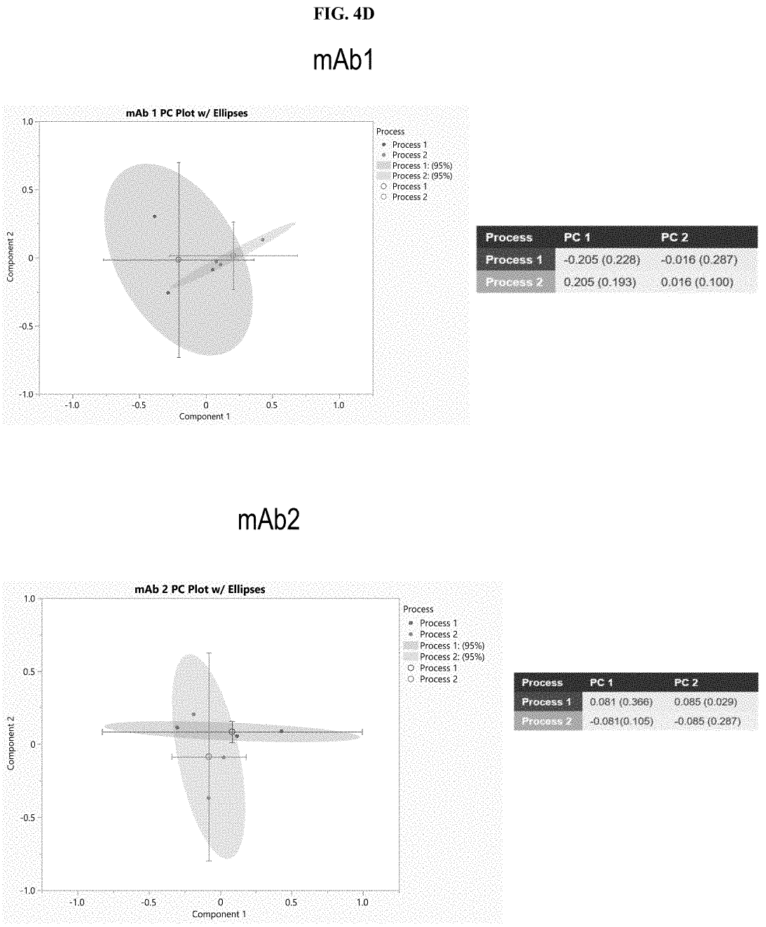

Additional analysis of process variability was conducted using PCA. Representative spectra for each antibody for each process were plotted against each other based on the scores of the top two principal components, as shown in FIG. 4A. 95% confidence density ellipses (“clusters”) grouped by manufacturing process were plotted. This analysis renders visible variation both between processes and within processes, allowing for more detailed understanding of antibody HOS variation with potential quality control relevance, compared to single lot-to-lot comparisons. In the example shown in FIGS. 4A and 4B, this PCA analysis reveals that, for mAb1, correlations in each component seem to be consistent between each process. In contrast, for mAb2, component 1 for Process 1 seems more variable than for Process 2, while component 2 for Process 2 seems more variable than for Process 1. FIGS. 4B and 4C also shows the variance breakdown in addition to spectral similarity number.

Data from this PCA analysis can be further interrogated using statistical analysis of the clusters of NMR spectra from each manufacturing process established above, as shown in FIG. 4D. Process variability can be quantified and compared in various ways, for example by taking the mean or standard variation of the spectra values on the PCA plot. This analysis provides a simple quantitative method for comparing variability between protein manufacturing processes.

What is claimed is:

1. A method for comparing manufacturing processes of at least one protein, comprising:
a. obtaining a plurality of samples from at least two manufacturing processes;
b. preparing said samples for NMR spectroscopy;
c. subjecting prepared samples to a NMR experiment;
d. obtaining NMR spectra for said samples from said NMR experiment;
e. averaging said spectra of each of said at least two manufacturing processes; and
f. comparing said averaged NMR spectra from said at least two manufacturing processes to detect differences in protein higher order structure.

2. The method of claim 1, wherein said protein is an antibody, a bispecific antibody, a multispecific antibody, antibody fragment, monoclonal antibody, antibody drug conjugate, antibody/targeted drug conjugate, conjugated monoclonal antibody, conjugated monoclonal antibody fragment, or an Fc fusion protein.

3. The method of claim 1, wherein said protein is a monoclonal antibody.

4. The method of claim 1, wherein preparing said samples for NMR spectroscopy includes a step of contacting said samples to at least one hydrolyzing agent.

5. The method of claim 4, wherein said hydrolyzing agent is immunoglobulin-degrading enzyme of Streptococcus pyogenes (IdeS) or a variant thereof.

6. The method of claim 1, wherein said NMR spectra are 2D-NMR spectra.

7. The method of claim 6, wherein said 2D-NMR spectra are obtained using a homonuclear NMR experiment through correlation spectroscopy (COSY), total correlation spectroscopy (TOCSY) or nuclear Overhauser effect spectroscopy (NOESY).

8. The method of claim 6, wherein said 2D-NMR spectra are obtained using a heteronuclear NMR experiment through ¹H—¹⁵N HSQC or ¹H—¹³C HSQC.

9. The method of claim 1, wherein comparison includes applying ECHOS-NMR on said averaged NMR spectra from said at least two manufacturing processes.

10. The method of claim 1 capable of comparing two manufacturing processes of protein.

11. A method for comparing manufacturing processes of at least one protein, comprising:
(a) obtaining a plurality of protein samples from at least two manufacturing processes;
(b) preparing said samples for NMR spectroscopy;
(c) subjecting said samples to a NMR experiment; and
(d) subjecting resulting NMR spectra to a principal component analysis to compare manufacturing processes to detect differences in protein higher order structure.

12. The method of claim 11, wherein said NMR spectra in said principal component analysis are clustered by manufacturing process.

13. The method of claim 12, further comprising subjecting said principal component analysis clusters to statistical analysis to compare manufacturing processes.

14. The method of claim 11, further comprising determining at least one area of said NMR spectra that contributes to at least one difference measured using principal component analysis, wherein said area is determined by plotting at least one loading as a contour plot on said NMR spectra.

15. The method of claim 11, wherein said protein is an antibody, a bispecific antibody, a multispecific antibody, antibody fragment, monoclonal antibody, or an Fc fusion protein.

16. The method of claim 11, wherein said protein is a monoclonal antibody.

17. The method of claim 11, wherein preparing said samples for NMR spectroscopy includes a step of contacting said samples to at least one hydrolyzing agent.

18. The method of claim 17, wherein said hydrolyzing agent is immunoglobulin-degrading enzyme of Streptococcus pyogenes (IdeS) or a variant thereof.

19. The method of claim 17, wherein said NMR spectra are 2D-NMR spectra.

20. The method of claim 19, wherein said 2D-NMR spectra are obtained using a homonuclear NMR experiment through correlation spectroscopy (COSY), total correlation spectroscopy (TOCSY) or nuclear Overhauser effect spectroscopy (NOESY).

21. The method of claim 19, wherein said 2D-NMR spectra are obtained using a heteronuclear NMR experiment through ¹H—¹⁵N HSQC or ¹H—¹³C HSQC.

22. The method of claim 11, wherein comparison includes applying ECHOS-NMR on said averaged NMR spectra from said at least two manufacturing processes.

23. The method of claim 11 capable of comparing two manufacturing processes of protein.

24. A method for characterizing a protein, comprising:
a. obtaining a protein sample;
b. preparing said sample for NMR spectroscopy;
c. subjecting said sample to a NMR experiment;
d. eliminating noise from empty areas of a resulting NMR spectrum; and
e. analyzing the NMR spectrum to characterize the protein.

25. The method of claim 24, wherein step (d) comprises:
(i) dividing the NMR spectrum into bins;
(ii) selecting an empty area of the NMR spectrum;
(iii) determining a standard deviation of signal intensity in the selected area to set a noise threshold; and
(iv) adjusting the NMR spectrum signal such that all bins with signal below two times the noise threshold are set to zero.

26. The method of claim 24, further comprising excluding bins with an intensity of zero from analysis.

27. The method of claim 24, wherein said protein is an antibody, a bispecific antibody, a multispecific antibody, antibody fragment, monoclonal antibody, or an Fc fusion protein.

28. The method of claim 24, wherein said protein is a monoclonal antibody.

29. The method of claim 24, wherein preparing said samples for NMR spectroscopy includes a step of contacting said samples to at least one hydrolyzing agent.

30. The method of claim 29, wherein said hydrolyzing agent is immunoglobulin-degrading enzyme of Streptococcus pyogenes (IdeS) or a variant thereof

31. The method of claim 24, wherein said NMR spectra is a 2D-NMR spectra.

32. The method of claim 31, wherein said 2D-NMR spectra is obtained using a homonuclear NMR experiment through correlation spectroscopy (COSY), total correlation spectroscopy (TOCSY) or nuclear Overhauser effect spectroscopy (NOESY).

33. The method of claim 31, wherein said 2D-NMR spectra is obtained using a heteronuclear NMR experiment through ¹—¹⁵N HSQC or ¹H—¹³C HSQC.
